(19) United States
(12) Patent Application Publication
(10) Pub. No.: US 2018/0108818 A1
(43) Pub. Date: Apr. 19, 2018

(54) LIGHT-EMITTING MODULE AND LIGHTING FIXTURE

(71) Applicant: PANASONIC INTELLECTUAL PROPERTY MANAGEMENT CO., LTD., Osaka (JP)

(72) Inventors: Kosuke TAKEHARA, Osaka (JP); Hisaki FUJITANI, Kyoto (JP); Masumi ABE, Osaka (JP)

(73) Assignee: PANASONIC INTELLECTUAL PROPERTY MANAGEMENT CO., LTD., Osaka (JP)

(21) Appl. No.: 15/715,592

(22) Filed: Sep. 26, 2017

(30) Foreign Application Priority Data
Oct. 17, 2016 (JP) 2016-203600

(51) Int. Cl. H01L 33/50; H01L 33/54; H01L 33/62; H01L 33/58

(52) U.S. Cl. CPC H01L 33/507; H01L 33/58; H01L 33/62; H01L 33/54

(57) ABSTRACT

A light-emitting module is provided. The light-emitting module includes a substrate, a light-emitting element mounted on the substrate, and a sealant that seals the light-emitting element. The sealant includes a resin material containing a wavelength converter. A cross section of the sealant taken through the light-emitting element satisfies H_{MAX}/W≤0.3, where W is a width of a base of the sealant and H_{MAX} is a maximum height of the sealant.

### CROSS REFERENCE TO RELATED APPLICATION

This application claims the benefit of priority of Japanese Patent Application Number 2016-203600 filed on Oct. 17, 2016, the entire content of which is hereby incorporated by reference.

### BACKGROUND

### 1. Technical Field

The present disclosure relates to a light-emitting module and a lighting fixture including a light-emitting module.

### 2. Description of the Related Art

Semiconductor light-emitting elements such as light-emitting diodes (LEDs) are widely used as light sources in a variety of devices due to their high efficiency and long life span. For example, LEDs are used as light sources for lighting purposes in, for example, lighting fixtures or lamps, and as backlight light sources in, for example, liquid crystal displays.

Typically, LEDs are used in various devices in units referred to as LED modules. An LED module includes, for example, a substrate and one or more LEDs mounted on the substrate (for example, see Japanese Unexamined Patent Application Publication No. 2011-176017).

One example of a known LED module is a chip on board (COB) type module in which one or more LEDs (LED chips) are directly mounted on a substrate. A COB type LED module includes, for example, a substrate, a plurality of LED chips mounted or the substrate, and a sealant that collectively seals the plurality of LED chips. For example, the sealant is made of a resin material containing phosphor. With this configuration, the light from the LED chips and the light from the phosphor mixes in the sealant, whereby light of a predetermined color is emitted from the sealant.

### SUMMARY

One problem with the structure of a conventional COB type LED module is that when there is a deviation in the positional relationship between an LED chip and the sealant, it results in an unevenness in color.

The present disclosure was conceived to overcome such a problem and has an object to provide a light-emitting module and lighting fixture capable of inhibiting color unevenness when there is a deviation in the positional relationship between a light-emitting element and the sealant.

In order to achieve the above-described object, a light-emitting module according to one aspect of the present invention includes a substrate, a light-emitting element mounted on the substrate, and a sealant that seals the light-emitting element. The sealant includes a resin material containing a wavelength converter. A cross section of the sealant taken through the light-emitting element satisfies H_{MAX}/W≤0.3, where W is a width of a base of the sealant and H_{MAX} is a maximum height of the sealant.

Moreover, a lighting fixture according to one aspect of the present invention includes the above-described light-emitting module.

According to the present disclosure, it is possible to inhibit color unevenness when there is a deviation in the positional relationship between a light-emitting element and the sealant.

### BRIEF DESCRIPTION OF DRAWINGS

The figures depict one or more implementations in accordance with the present teaching, by way of examples only, not by way of limitations. In the figures, like reference numerals refer to the same or similar elements.

FIG. 1 is a plan view of the light-emitting module according to Embodiment 1;

FIG. 2 is a cross sectional view of part of the light-emitting module according to Embodiment 1, taken at line II-II in FIG. 1;

FIG. 3 is a cross sectional view of the light-emitting module according to Embodiment 1, taken at line III-III in FIG. 1;

FIG. 4 illustrates a contour of a cross section of a sealant in a light-emitting module according to an embodiment;

FIG. 5 schematically illustrates how light emitting from a light-emitting module (sealant) is measured;

FIG. 6 illustrates the relationship between the height to width ratio of a sealant in a light-emitting module and unevenness in color;

FIG. 7A is a cross sectional view illustrating the process of applying a sealant material in the manufacturing method of the light-emitting module according to Embodiment 1;

FIG. 7B is a side view illustrating the process of applying a sealant material in the manufacturing method of the light-emitting module according to Embodiment 1;

FIG. 8A is a cross sectional view of a light-emitting module according to a comparative example when there is no deviation in the positional relationship between a light-emitting element and the sealant;

FIG. 8B is a cross sectional view of a light-emitting module according to a comparative example when there is a deviation in the positional relationship between a light-emitting element and the sealant;

FIG. 9 is a cross sectional view of a light-emitting module illustrating one example of when there is a deviation in the positional relationship between a light-emitting element and the sealant;

FIG. 10 is a cross sectional view of a light-emitting module illustrating another example of when there is a deviation in the positional relationship between a light-emitting element and the sealant;

FIG. 11A is a cross sectional view of a light-emitting module according to an embodiment when there is no deviation in the positional relationship between a light-emitting element and the sealant;

FIG. 11B is a cross sectional view of a light-emitting module according to an embodiment when there is a deviation in the positional relationship between a light-emitting element and the sealant;

FIG. 12 is a perspective cross sectional view of the lighting fixture according to Embodiment 2;

FIG. 13 is a cross sectional view of the lighting fixture according to Embodiment 2;

FIG. 14 is a cross sectional view of the light-emitting module according to Variation 1;

FIG. 15 is a plan view of the light-emitting module according to Variation 2;

FIG. 16 is a plan view of the light-emitting module according to Variation 3; and

FIG. 17 is a plan view of the light-emitting module according to Variation 4.

### DETAILED DESCRIPTION OF THE EMBODIMENTS

The following describes exemplary embodiments of the present disclosure. Each of the embodiments described below is merely one specific example of the present disclosure. The numerical values, shapes, materials, elements, arrangement and connection of the elements, steps, and order of the steps, etc., indicated in the following embodiments are given merely by way of illustration and are not intended to limit the present disclosure. Therefore, among elements in the following embodiments, those not recited in any one of the independent claims defining the broadest inventive concept of the present disclosure are described as optional elements.

Note that the figures are schematic illustrations and are not necessarily precise depictions. Accordingly, the figures are not necessarily to scale. Moreover, in the figures, elements that are essentially the same share like reference signs. Accordingly duplicate description is omitted or simplified.

Moreover, in the detailed description and drawings, the X, Y, and Z axes indicate the three axes in a three-dimensional orthogonal coordinate system, and in this embodiment, directions parallel to the Z axis extend in vertical directions, and directions perpendicular to the Z axis (i.e., directions parallel to the XY plane) extend in horizontal directions. The X and Y axes are orthogonal to one another and the Z axis.

### Embodiment 1

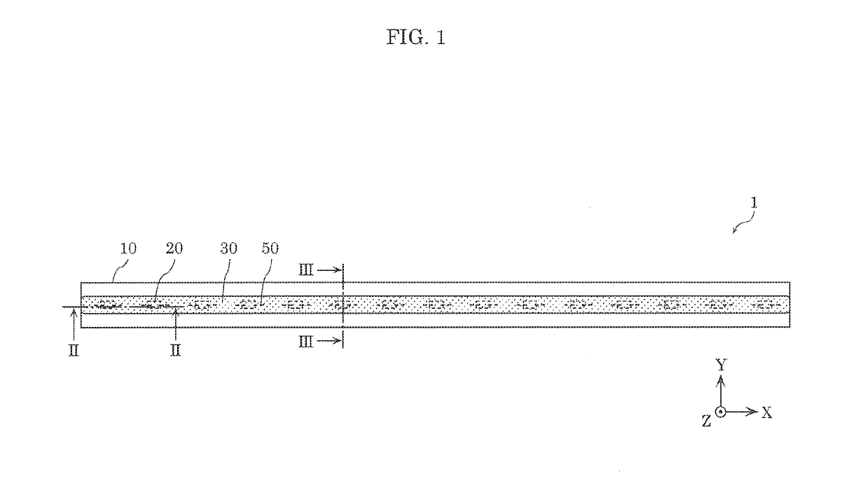

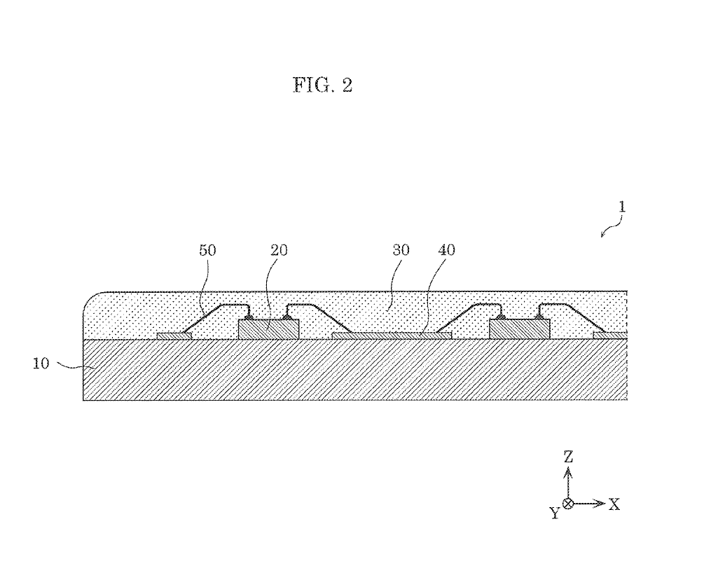

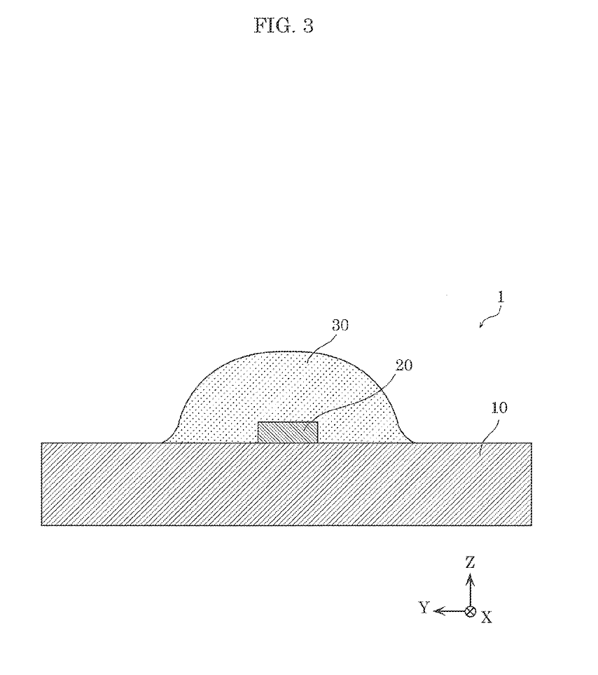

The configuration of light-emitting module 1 according to Embodiment 1 will be described with reference to FIG. 1 through FIG. 3. FIG. 1 is a plan view of light-emitting module 1 according to Embodiment 1. FIG. 2 is a cross sectional view of part of light-emitting module 1 according to Embodiment 1, taken at line II-II in FIG. 1. FIG. 3 is a cross sectional view of light-emitting module I according to Embodiment 1, taken at line III-III in FIG. 1.

As illustrated in FIG. 1 through FIG. 3, light-emitting module 1 includes substrate 10, light-emitting elements 20, sealant 30, printed wiring 40, and wires 50.

Light-emitting module 1 according to this embodiment is a linear light source that emits light in a line. Light-emitting module 1 according to this embodiment emits, for example, white light. Moreover, light-emitting module 1 is a COB type LED module in which LED chips, corresponding to light-emitting elements 20, are directly mounted onto substrate 10.

Hereinafter, each element included in light-emitting module 1 will be described in detail with reference to FIG. 1 through FIG. 3.

### (Substrate)

Substrate 10 is a mounting substrate for mounting light-emitting elements 20. For example, a ceramic substrate made of ceramic, a resin substrate including resin as a base material, a metal-based substrate including metal as a base material, or a glass substrate made of glass can be used as substrate 10.

For example, an alumina substrate made of alumina or an aluminum nitride substrate made of aluminum nitride can be used as the ceramic substrate. For example, a glass epoxy substrate made of fiberglass and epoxy resin (for example, CEM-3 or FR-4), a substrate made of paper-based phenol or paper-based epoxy (for example, FR-1), or a flexible substrate made of, for example, polyimide, can be used as the resin substrate. For example, an aluminum alloy, iron alloy, or copper alloy substrate whose surface is covered with an electrically insulating film can be used as the metal-based substrate. Note that substrate 10 is not limited to a rigid substrate, and may be a flexible substrate.

A white substrate having a high reflectivity (for example, a reflectivity of at least 90%) is desirably used as substrate 10. Using a white substrate makes it possible to reflect light from light-emitting elements 20 off the surface of substrate 10, thereby increasing the light extraction efficiency of light-emitting module 1. In this embodiment, a white ceramic substrate is used as substrate 10. In this case, a white polycrystalline alumina substrate (polycrystalline ceramic substrate) formed by sintering alumina particles and having, for example, a thickness of approximately 1 mm, can be used as substrate 10. Ceramic substrates have a higher thermal conductivity than resin substrates, and can efficiently dissipate heat generated by light-emitting elements 20. Moreover, ceramic substrates have a low deterioration rate, and are highly heat resistant.

In this embodiment, substrate 10 has the shape of an oblong rectangle. In other words, substrate 10 has an oblong rectangle plan view shape. For example, the aspect ratio (L1/L2) of oblong substrate 10 satisfies L1/L2≥10, where L1 is the measurement of substrate 10 in the lengthwise direction (length of a long side) and L2 is the measurement of substrate 10 in the crosswise direction (length of a short side).

A pair of electrode terminals for receiving, from a source external to light-emitting module 1, DC power for causing light-emitting elements 20 to emit light is disposed on substrate 10. The pair of electrode terminals is electrically connected to a power supply device (power supply circuit) via, for example, a lead wire. The power received by the pair of electrode terminals is supplied to light-emitting elements 20 via printed wiring 40

### (Light-Emitting Elements)

Light-emitting elements 20 are one example of semiconductor light-emitting elements, and emit light upon receiving predetermined power. In this embodiment, light-emitting elements 20 are bare chips (LED chips) that emit monochromatic visible light, and are, for example, blue LED chips that emit blue light when current passes therethrough. Gallium nitride semiconductor light-emitting elements having a center wavelength in a range of from 440 nm to 470 nm, inclusive, can be used as the blue LED chips. In one example, the blue LED chips are semiconductor light-emitting elements having a one-sided electrode structure in which both p and n electrodes are formed on the top surface of an InGaN nitride semiconductor layer formed on a sapphire substrate. Note that light-emitting elements 20 may have a two-sided electrode structure.

Light-emitting elements 20 are disposed on substrate 10. In this embodiment, light-emitting elements 20 are directly mounted on one major surface of substrate 10. More specifically, light-emitting elements 20 are die bonded to a surface (in this embodiment, the ceramic surface) of substrate 10 using, for example, a die attachment substance. Light-emitting elements 20 mounted on substrate 10 are covered by sealant 30.

Moreover, light-emitting elements 20 are mounted in a single line. In this embodiment, substrate 10 is oblong, and light-emitting elements 20 are mounted arranged in a straight line along the lengthwise direction of substrate 10. More specifically, light-emitting elements 20 are arranged in no more than one line along the lengthwise direction of substrate 10. Moreover, light-emitting elements 20 are arranged spaced apart from one another at a uniform pitch, whereby the distance between two adjacent light-emitting elements 20 is the same, but the arrangement of light-emitting elements 20 is not limited to this example.

Note that in this embodiment, two adjacent light-emitting elements 20 are electrically connected via printed wiring 40 and wires 50 disposed between the two adjacent light-emitting elements 20, but the configuration is not limited to this example. For example, light-emitting elements 20 may be configured such that two adjacent light-emitting elements 20 are directly connected via wire 50. In other words, two adjacent light-emitting elements 20 may be wire bonded in a chip-to-chip configuration. Moreover, light-emitting elements 20 may be connected to printed wiring 40 in a flip chip connection without the use of wires 50.

### (Sealant)

Sealant 30 seals light-emitting elements 20. More specifically, sealant 30 is formed on substrate 10 so as to cover light-emitting elements 20. Sealant 30 collectively seals light-emitting elements 20 arranged in a straight line. In other words, sealant 30 extends in a straight line on a major surface of substrate 10 along the arrangement direction of light-emitting elements 20. This makes it possible to produce a light emitter that continuously extends in a straight line.

In this embodiment, sealant 30 extends along the lengthwise direction of substrate 10. More specifically, sealant 30 extends from one of the two short sides of substrate 10 to the other. In other words, sealant 30 extends to both edges in the lengthwise direction of the substrate 10, and extends continuously, without interruption, from one short side of substrate 10 to the other opposing short side of substrate 10.

Sealant 30 is made of a resin material containing a wavelength converter. An electrically insulating resin material having light-transmissive properties, such as a silicon resin, epoxy resin, or fluorocarbon resin can be used as the resin material for sealant 30. The wavelength converter contained in sealant 30 converts the wavelength of light emitted by light-emitting elements 20 into a predetermined wavelength. In this embodiment, sealant 30 contains phosphor as the wavelength converter, and thus is a phosphor-containing resin, which is a resin material dispersed with phosphor. The phosphor in sealant 30 is excited by light emitted by light-emitting elements 20, which produces fluorescence, resulting in the radiation of light of a predetermined color (wavelength).

In this embodiment, since blue LED chips are used as light-emitting elements 20, in order to produce white light, for example, yttrium aluminum garnet (YAG) yellow phosphor can be used as the phosphor. With this, a portion of the blue light emitted by the blue LED chips is absorbed by the yellow phosphor and wavelength-converted into yellow light. In other words, the yellow phosphor is excited by the blue light from the blue LED chips and. radiates yellow light. The yellow light from the yellow phosphor mixes with the blue light not absorbed by the yellow phosphor to produce white light as synthesized light, whereby white light is emitted from sealant 30.

Note that in order to improve color rendering properties, sealant 30 may additionally contain red phosphor. Moreover, a light diffusing material, such as silica, may be diffused in sealant 30 to improve the light diffusion properties of sealant 30, and a filler may be diffused in sealant 30 to inhibit the phosphor from settling.

Sealant 30 can be formed by using a dispenser to apply the material (phosphor-containing resin) used for sealant 30 onto a major surface of substrate 10 in the arrangement direction of light-emitting elements 20, so as to cover light-emitting elements 20, and then curing the material.

Sealant 30 has a low-profile, semi-cylindrical shape. Although the cross sectional shape of sealant 30 will be described in further detail later, a YZ cross section of sealant 30 has a low profile that satisfies H_{MAX}/W≤0.3, where W is the width of the base of sealant 30 and H_{MAX} is the maximum height of sealant 30. Sealant 30 desirably has a low-profile shape as described above, but the height to width ratio of sealant 30 is preferably not too low. For example, the height to width ratio of sealant 30 desirably satisfies 0.1≤H_{MAX}/W. In one example, the contour of the surface of sealant 30 in a YZ cross section has an overall curved shape.

### (Printed Wiring)

Printed wiring 40 is, for example, metallic printed wiring, and is printed into a predetermined pattern on a major surface of substrate 10 so as to electrically interconnect light-emitting elements 20. Printed wiring 40 includes, for example, lands between adjacent light-emitting elements 20 and a pair of traces connected to the pair of electrode terminals on substrate 10. For example, copper (Cu) or silver (Ag) can be used as the metal material for printed wiring 40. Note that the surfaces of printed wiring 40 may be covered with, for example, a film of gold (Au) by plating.

For example, printed wiring 40 is printed so as to connect light-emitting elements 20 mounted on substrate 10 in series or parallel, or to connect light-emitting elements 20 in a combination of series and parallel connections.

Moreover, although not illustrated in the drawings, an electrically insulating film, made of, for example, glass (glass coat film) or an electrically insulating resin (resin coat film), may be formed on the surface of substrate 10 so as to cover printed wiring 40. For example, a highly reflective white resin material (white resist) having a reflectivity of approximately 98% can be used as the electrically insulating film. Note that one or more openings that expose part of printed wiring 40 so that printed wiring 40 and light-emitting elements 20 can be connected via wires 50 are formed in the electrically insulating film. The electrically insulating film is formed across entire surface of substrate 10 except for the area or areas corresponding to the one or more openings.

In this way, by covering the entire substrate 10 with an electrically insulating film such as a white resist or glass coat film, light emitted from sealant 30 can be reflected, thereby increasing the light extraction efficiency of light-emitting module 1. Moreover, by covering printed wiring 40 with an electrically insulating film, the dielectric strength of substrate 10 can be increased and oxidation of printed wiring 40 can be inhibited.

### (Wires)

Wires 50 are connected to each light-emitting element 20. In this embodiment, a pair of wires 50 is connected to each tight-emitting element 20. Wires 50 are connected to, for example, light-emitting elements 20 and printed wiring 40 (lands) printed on substrate 10. In other words, light-emitting elements 20 and printed wiring 40 are connected together by wire bonding via wires 50, where one end of wire 50 is connected to light-emitting element 20 and the other end of wire 50 is connected to printed wiring 40. This electrically connects light-emitting elements 20 and printed wiring 40 via wires 50. Wires 50 are, for example, metal wires such as gold wires, and are disposed such that each wire 50 extends between a light-emitting element 20 and printed wiring 40 using a capillary.

Wires 50 are sealed by sealant 30. In this embodiment, each wire 50 is completely covered by sealant 30, but a portion of wire 50 may be exposed from sealant 30. Moreover, wires 50 are disposed so as to extend in the lengthwise direction of sealant 30. In other words, in a plan view, wires 50 connected to light-emitting elements 20 are disposed in a straight line.

### (Sealant Shape)

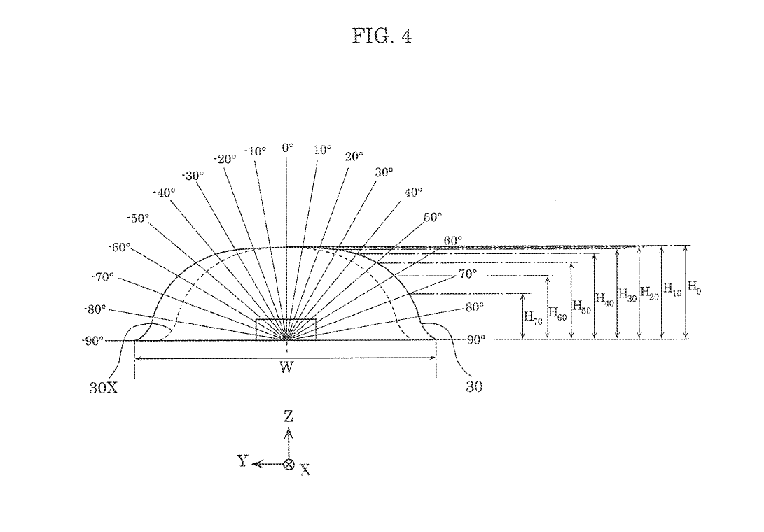

Next, the shape of sealant 30 in light-emitting module 1 will be described with reference to FIG. 4. FIG. 4 illustrates the contour (outline) of a cross section of sealant 30 in light-emitting module 1 according to Embodiment 1, the cross section taken through light-emitting element 20. More specifically, the cross section in FIG. 4 is a crosswise cross section of sealant 30 that passes through the central region of light-emitting element 20.

Note that in FIG. 4, the solid line indicates the contour of sealant 30 in light-emitting module 1 according to this embodiment, and the broken line indicates the contour of sealant 30X in a light-emitting module according to a comparative example.

As illustrated in FIG. 4, in cross sections of sealant 30 and sealant 30X taken through light-emitting element 20, when the width of the base of sealant 30 and sealant 30X is expressed as W and the maximum height of sealant 30 is expressed as H_{MAX}, the ratio (height to width ratio) of the maximum height H_{MAX} to the width W is expressed as H_{MAX}/W. Moreover, in this embodiment, in the cross sections of sealant 30 and sealant 30X in FIG. 4, H₀=H_{MAX}, where the direction pointing straight upward from the center of the base of sealant 30 is 0 degrees, and H₀ is the height of sealant 30 at the center of the base of sealant 30. In other words, the maximum height of each of sealant 30 and sealant 30X is located in the central region.

In this embodiment, the width W of the base of sealant 30 satisfies 2.2 mn≤W≤2.5 mm. The width of each light-emitting element 20 is in a range of from approximately 0.3 mm to 0.5 mm, inclusive.

The dependency between the height to width ratio (H_{MAX}/W) of sealant 30 of light-emitting module 1 and unevenness in color of the light emitted from sealant 30 was measured by experiment. Next, the experiment will be described.

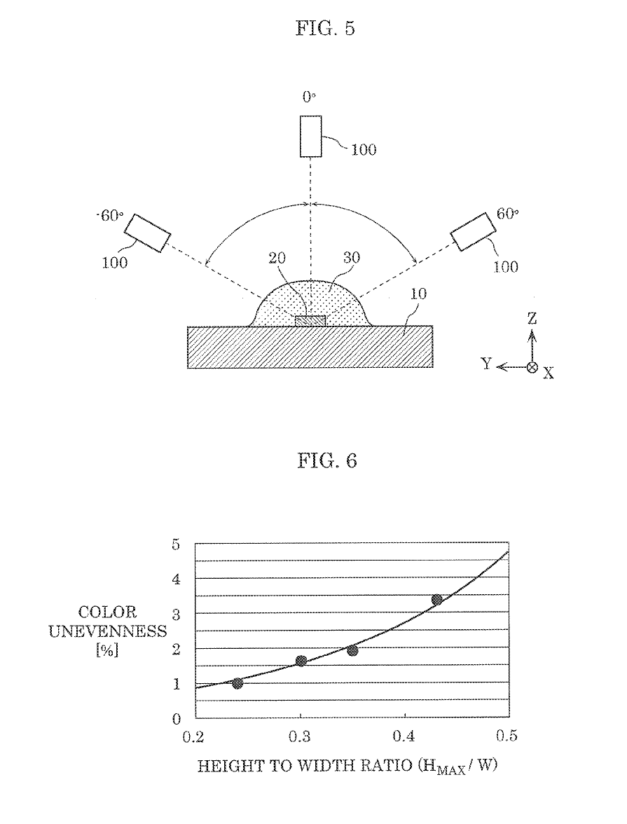

The light emitted from sealant 30 of light-emitting module 1 can be measured at a predetermined angle using a goniometer. In this experiment, as illustrated in FIG. 5, using light-emitting module 1 as the sample, the color temperature of light emitted from sealant 30 and passing through movable fiber 100 was measured at predetermined angles using a spectrometer.

In this experiment, as illustrated in FIG. 5, the color temperature was measured at angles of +60 degrees and −60 degrees relative to the central region (0 degrees) of sealant 30, and unevenness in color was calculated based on the difference in color temperature. More specifically, the unevenness in color Z was calculated as Z(%)=1−(T2/T1), where T1 is the higher of the color temperatures measured at +60 degrees and −60 degrees, and T1 is the lower of the color temperatures measured at +60 degrees and −60 degrees. Note that due to, for example, the light from the LED chips being Lambertian distributed light, the light at the positions +60 degrees and −60 degrees was tested.

Moreover, the height to width ratio of sealant 80 was changed multiple times aid the unevenness in color of light-emitting module 1 (sealant 30) was calculated for each time. Here, the height to width ratio of sealant 30 was changed by adjusting the conditions of the dispenser (discharge amount, nozzle height) used to apply the material (resin) for forming sealant 30. More specifically, under each condition, the nozzle position was offset to artificially generate positional deviations between the material applied to form sealant 30 and the positions of light-emitting elements 20, and the unevenness in color was calculated. In this experiment, the relationship between the height to width ratio (H_{MAX}/W) of sealant 30 and unevenness in color was calculated with a positional deviation set, to 60 μm.

The result is illustrated in FIG. 6. FIG. 6 illustrates the relationship between the height to width ratio of sealant 30 in light-emitting module 1 and the unevenness in color. As illustrated in FIG. 6, since the unevenness in color is preferably 1.5% or less, the results show that the height to width ratio (H_{MAX}/W) of sealant 30 is desirably 0.3 or less.

Accordingly, in light-emitting module 1 according to this embodiment, sealant 30 satisfies H_{MAX}/W≤0.3. This makes it possible to effectively inhibit color unevenness even when a deviation in the positional relationship between light-emitting element 20 and sealant 30 arises.

Note that in FIG. 4, sealant 30 indicated by the solid line satisfies W=2.31 mm and H_{MAX}=0.7 mm, and therefore the height to width ratio of sealant 30 is H_{MAX}/W≈0.30. Note that the sealant indicated by the broken line satisfies W=1.97 mm and HMAX=0.687 mm, and therefore the height to width ratio of the sealant is HMAX/W≈0.35.

Moreover, as illustrated in sealant 30 indicated by the solid line in FIG. 4, sealant 30 desirably has a 17, cross sectional shape that satisfies H₀=1.00 (100%), H₁₀≥0.95 (95%), H₂₀/H₀≥0.95 (95%), H₃₀/H₀≥0.95 (95%), H₄₀/H₀≥0.90 (90%), H₅₀/H₀≥0.80 (80%), H₆₀/H₀≥0.70 (70%), and H₇₀/H₀≥0.65 (65%), where H₀, H₁₀, H₂₀, H₃₀, H₄₀, H₅₀, H₆₀, and H₇₀ are respective heights of sealant 30 in directions of 0 degrees, 1.0 degrees, 20 degrees, 30 degrees, 40 degrees, 50 degrees, 60 degrees, and 70 degrees from the center of the base of sealant 30.

In this embodiment, sealant 30 has symmetry about a vertical axis. Accordingly, sealant 30 desirably satisfies H₋₁₀≥0.95 (95%), H₋₂₀/H₀≥0.95 (95%), H₋₃₀/H₀≥0.95 (95%), H₋₄₀/H₀≥0.90 (90%), H₋₅₀/H₀≥0.80 (80%), H₋₆₀/H₀≥0.70 (70%), and H₋₇₀/H₀≥0.05 (65%), where H₋₁₀, H₋₉₀, H₋₃₀, H₋₄₀, H₋₅₀, H₋₆₀, and H₋₇₀ are respective heights of sealant 30 in directions of −10 degrees, −20 degrees, −30 degrees, −40 degrees, −50 degrees, −60 degrees, and −70 degrees from the center of the base of sealant 30.

In one example, sealant 30 illustrated in FIG. 4 satisfies H₀=1.00 (100%), H₁₀=H₋₁₀=1.00 (100%), H₂₀=H₋₂₀=0.99 (99%), H₃₀=H₋₃₀=0.97 (97%), H₄₀=H₋₄₀=0.93 (93%), H₅₀=H−₅₀=0.84 (84%), H₆₀=H₋₆₀=0.70 (70%), and H₋₇₀/H₀≥0.65 (65%).

Note that since the light from light-emitting elements 20 (LET) chips) is Lambertian distributed, the heights of sealant 30 at 60 degrees and −60 degrees (H₆₀, H₋₆₀) in particular are critical. Accordingly, it is desirable that at least H₆₀/H₀≥0.65 and H₋₆₀/H₀≥0.65 be satisfied.

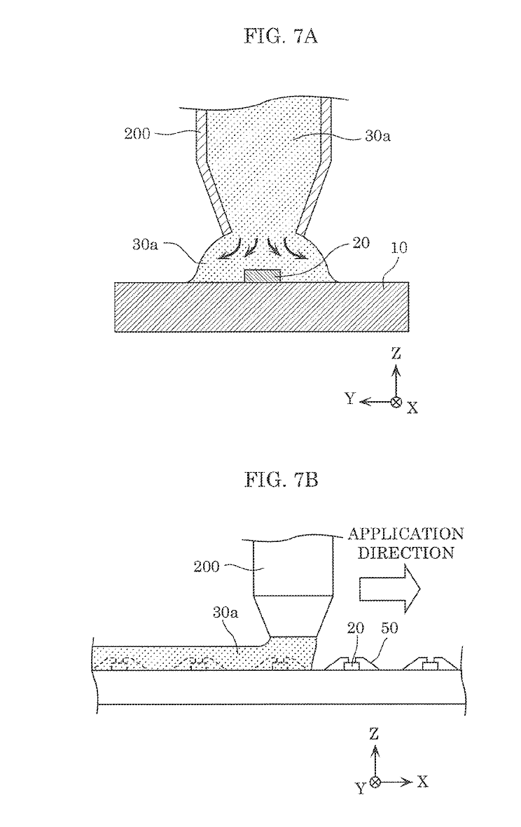

Sealant 30 can be formed so as to have such a shape using the method illustrated in FIG. 7A and FIG. 7B. FIG. 7A and FIG. 7B illustrate the process of applying sealant material 30a in the manufacturing method of light-emitting module 1 according to Embodiment 1. FIG. 7A is a cross sectional view, and FIG. 7B is a side view. Note that in FIG. 7A and FIG. 7B, illustration of printed wiring 40 is omitted.

As illustrated in FIG. 7A and FIG. 7B, sealant 30 is formed by applying sealant material 30a to substrate 10 using a dispenser.

More specifically, discharge nozzle 200 (dispenser nozzle) of the dispenser is orientated so as to face substrate 10, and discharge nozzle 200 is moved along the lengthwise direction of substrate 10 while sealant material 30a is discharged from discharge nozzle 200 along the row of light-emitting elements 20 mounted in a straight line on substrate 10, so as to cover light-emitting elements 20. Here, sealant material 30a is discharged so as to cover printed wiring 40 and wires 50 in addition to light-emitting elements 20.

In this embodiment, sealant material 30a is applied by moving discharge nozzle 200 in a single motion from one short side edge of substrate 10 to the other short side edge, but the application is not limited to this example.

A resin material containing phosphor (phosphor-containing resin) can be used as sealant material 30a that is applied. A resin material having a viscosity (at room temperature) of from 20 to 120 Pa·s, inclusive, and a thixotropic ratio (6 rpm/60 rpm) of from 2 to 10, inclusive, can be used. More preferably, a resin material, having a viscosity (at room temperature) of from 30 to 60 Pa·s, inclusive, and a thixotropic ratio (6 rpm/60 rpm) of from 4 to 6, inclusive, may be used. In one example, the resin material included in sealant material 30a is a thermosetting silicon resin.

In this embodiment, sealant material 30a is applied so as to achieve a low-profile YZ cross sectional shape. Here, sealant material 30a can be applied so as to have a predetermined height to width ratio that achieves the low-profile shape by adjusting the conditions of the dispenser (discharge amount, nozzle height) used to apply sealant material 30a. Here, sealant material 30a can be applied so as to easily achieve a low-profile cross sectional shape by, for example, using a large diameter nozzle as discharge nozzle 200, narrowing the distance between discharge nozzle 200 and substrate 10, and increasing the application amount (discharge amount per unit time) of sealant material 30a. Moreover, sealant material 30a can be applied so as to easily achieve a low-profile cross sectional shape by, for example, narrowing the distance between discharge nozzle 200 and substrate 10 and moving discharge nozzle 200 so as to push and spread the discharged sealant material 30a.

Note that after sealant material 30a is applied to substrate 10, sealant material 30a is cured by applying heat. This makes it possible to form sealant 30 having a straight line plan view shape and a low-profile cross sectional shape.

### (Light-Emitting Module Working Effects, Etc.)

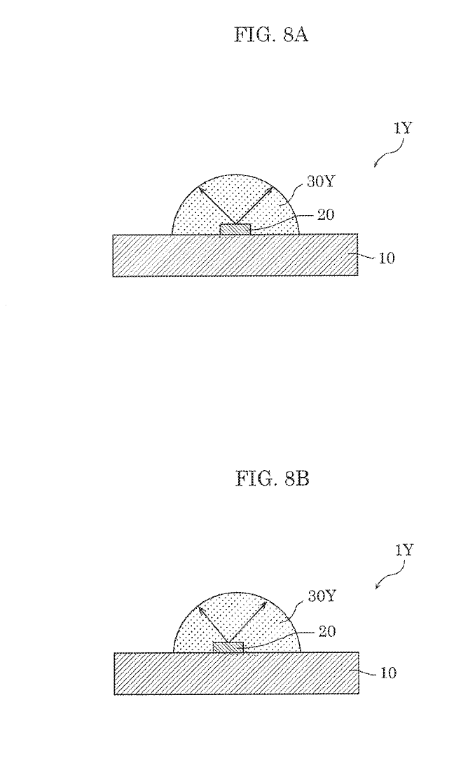

Next, the working effects, etc., of light-emitting module 1 according to Embodiment 1 as well as how the present disclosure was arrived at will be described with reference to FIG. 8A through FIG. 11B.

FIG. 8A and FIG. 8B are cross sectional views of light-emitting module 1Y according to a comparative example. FIG. 8A illustrates a case in which there is no deviation in the positional relationship between light-emitting element 20 and sealant 30Y, and FIG. 8B illustrates a case in which there is a deviation in the positional relationship between light-emitting element 20 and sealant 30Y.

As illustrated in FIG. 8A, when there is no deviation in the positional relationship between light-emitting element 20 and sealant 30Y in the COB type light-emitting module 1Y, sealant 30Y does not produce an unevenness in color since there is no difference in the lengths of the paths through sealant 30Y of the light emitted by light-emitting element 20.

In contrast, as illustrated in FIG. 8B, when there is a deviation in the positional relationship between light-emitting element 20 and sealant 30Y, there is a difference between the length of the path of light traveling diagonally up and to the left from light-emitting element 20 in sealant 30Y and the length of the path of light traveling diagonally up and to the right from light-emitting element 20 in sealant 30Y. This results in different colors on the left and right sides, i.e., an unevenness in color. For example, when light-emitting element 20 is a blue LED chip and sealant 30Y contains yellow phosphor, the light traveling along the shorter path appears bluer in color, and the light traveling along the longer path appears yellower in color.

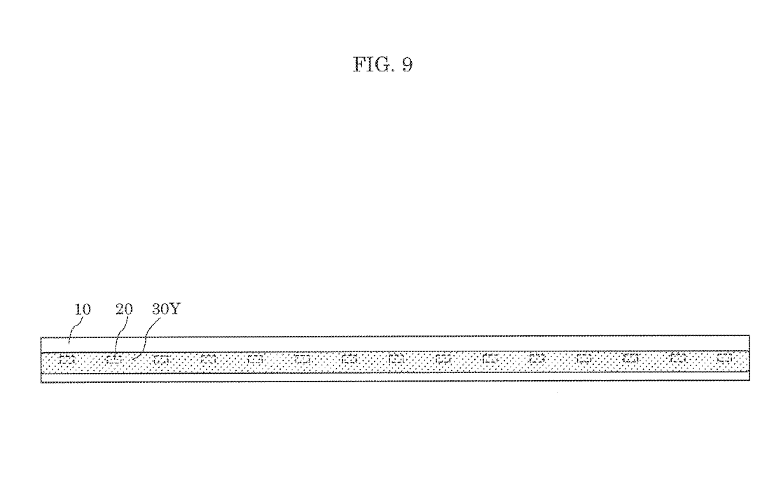

One example of such a deviation in the positional relationship between light-emitting element 20 and sealant 30Y is, for example, as illustrated in FIG. 9, when light-emitting elements 20 are accurately mounted in a single line such that there is no positional deviation with regard to light-emitting elements 20 themselves, but when sealant material 30a is applied, the position of sealant material 30a deviates from the line of light-emitting elements 20, thereby resulting in a deviation in the positional relationship between light-emitting elements 20 and sealant 30Y.

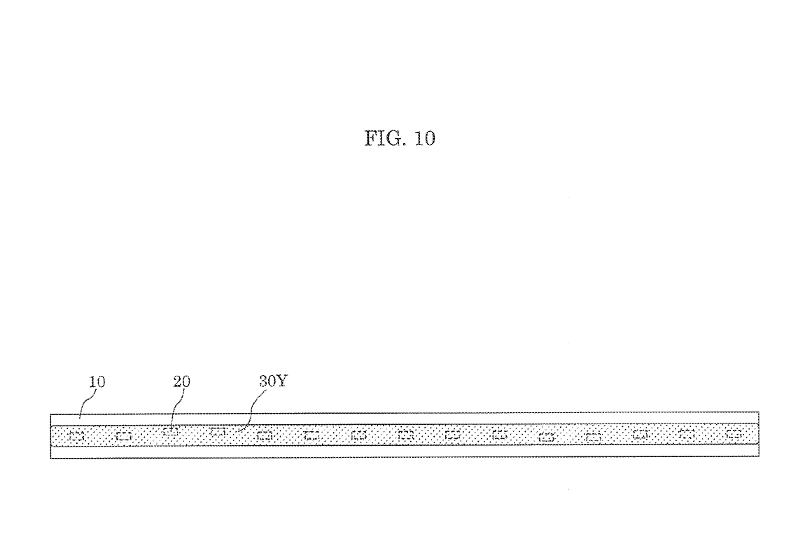

Another example of such a deviation in the positional relationship between light-emitting element 20 and sealant 30Y is, for example, as illustrated in FIG. 10, when light-emitting elements 20 are die bonded in a straight line, some light-emitting elements 20 are bonded in positions that deviate from the predetermined bonding positions, thereby resulting in a deviation in the positional relationship between some light-emitting elements 20 and sealant 30Y.

Note that when sealant material 30a having the above described viscosity and thixotropic ratio is formed so as to have a width of from 2.2 mm to 2.5 mm, inclusive and light-emitting elements 20 each have a width of from 0.3 mm to 0.5 mm, inclusive, the amount of positional deviation that arises when sealant material 30a is applied as illustrated in FIG. 9 is, at most, approximately 30 μm. Moreover, in this case, the amount of positional deviation that arises when light-emitting elements 20 are bonded as illustrated in FIG. 10 is, at most, approximately 30 μm. In other words, the total maximum amount of positional deviation that arises when there is a positional deviation between light-emitting element 20 and sealant 30Y is approximately 60 μm.

In this way, when there is a deviation in the positional relationship between light-emitting element 20 and sealant 30Y, this results in differences in the distances that the light travels radially from light-emitting element 20 through sealant 30Y (path lengths), leading to the problem of unevenness in color.

In particular, for example, with wallwasher lighting fixtures, where an oblong light-emitting module is used in a lighting fixture that emits light in two directions relative to the lighting fixture, such as to the left and right of the lighting fixture or above and below the lighting fixture, the unevenness in color is apparent.

As a result of diligent examination of this problem on the part of the inventors, they discovered that by forming sealant 30 so as to have a low profile, even in cases where a deviation arises in the positional relationship between light-emitting element 20 and sealant 30, unevenness in color can be inhibited by reducing the maximum difference in path lengths among the light radially emitted from light-emitting element 20.

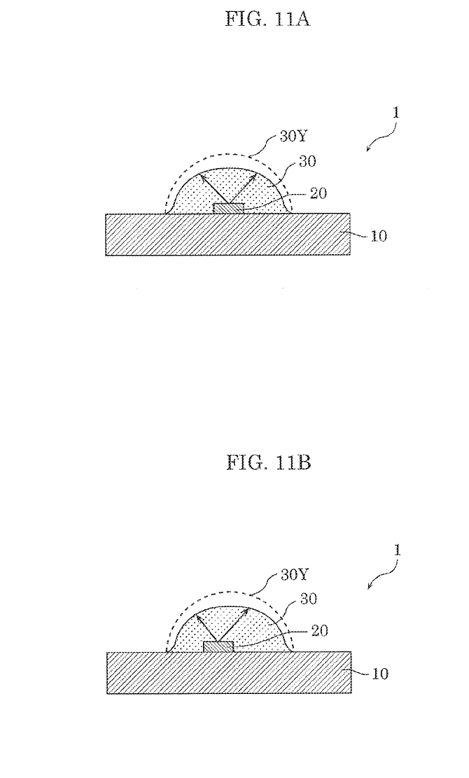

More specifically as illustrated in FIG. 11A and FIG. 11B, in light-emitting module 1 according to this embodiment, sealant 30 has a low profile that satisfies H_{MAX}/W≤0.3.

With this, as illustrated in FIG. 11A, when there is no deviation in the positional relationship between light-emitting element 20 and sealant 30, there is no difference between the length of the path of light traveling diagonally up and to the left from light-emitting element 20 in sealant 30 and the length of the path of light traveling diagonally up and to the right from light-emitting element 20 in sealant 30.

Moreover, as illustrated in FIG. 11B, even when there is a deviation in the positional relationship between light-emitting element 20 and sealant 30, the difference between the length of the path of light traveling diagonally up and to the left from light-emitting element 20 in sealant 30 and the length of the path of light traveling diagonally up and to the right from light-emitting element 20 in sealant 30 is smaller than in the example in FIG. 8B. In other words, this makes it possible to inhibit color unevenness when there is a deviation in the positional relationship between light-emitting element 20 and sealant 30.

### SUMMARY

Light-emitting module 1 according to this embodiment includes substrate 10, light-emitting element 20 mounted on substrate 10, and sealant 30 that seals light-emitting element 20. Sealant 30 includes a resin material containing a wavelength converter. A cross section of sealant 30 taken through light-emitting element 20 satisfies H_{MAX}/W≤0.3.

With this, since sealant 30 has a low-profile cross section, even when there is a deviation in the positional relationship between light-emitting element 20 and sealant 30, the difference in the lengths of paths of light emitted radially from light-emitting element 20 can be reduced. For example, when there is a deviation in the positional relationship between light-emitting element 20 and sealant 30, in a YZ cross section of sealant 30, even if there is a difference between the length of the path of light traveling diagonally up and to the left from light-emitting element 20 and the length of the path of light traveling diagonally up and to the right from light-emitting element 20, the difference between the lengths of the paths can be reduced more so than when the sealant does not have a low-profile cross section (for example, when the sealant has a semicircular cross section), so color unevenness can be inhibited.

Moreover, in light-emitting module 1 according to this embodiment, sealant 30 has a shape that further satisfies 0.1≤H_{MAX}/W.

When sealant 30 has a shape that satisfies H_{MAX}/W>0.3, sealant 30 is excessively flattened, whereby the difference between lengths of the paths of the light traveling directly upward from light-emitting element 20 and the light traveling diagonally up and to the left and right from light-emitting element 20 excessively increases, resulting in a chance for an unevenness in the color of light directly above sealant 30 and the color of light diagonally above sealant 30 to be noticeably apparent. Accordingly, sealant 30 desirably has a shape that satisfies 0.1≤H_{MAX}/W.

Note that since light traveling directly upward from light-emitting element 20 is higher in luminous flux than light traveling diagonally up and to the left and. right from light-emitting element 20, if sealant 30 has a shape that satisfies H_{MAX}/W≤0.3, the color unevenness between light directly above sealant 30 and light diagonally up and to the right and left of sealant 30 is inconspicuous.

Moreover, in light-emitting module 1 according to this embodiment, sealant 30 has a shape that further satisfies H₀=H_{MAX}.

This makes it possible to achieve sealant 30 having symmetry about a vertical axis in a YZ cross section, and thus makes it possible to further inhibit color unevenness.

Moreover, in light-emitting module 1 according to this embodiment, sealant 30 has a shape that further satisfies H₃₀/H₀≥0.95.

This makes it possible to broaden the acceptable range of the inhibiting effect of color unevenness when there is a deviation in the positional relationship between light-emitting element 20 and sealant 30.

Moreover, in light-emitting module 1 according to this embodiment, sealant 30 has a shape that further satisfies H₄₀/H₀≥0.90.

This makes it possible to further broaden the acceptable range of the inhibiting effect of color unevenness when there is a deviation in the positional relationship between light-emitting element 20 and sealant 30.

Moreover, in light-emitting module 1 according to this embodiment, sealant 30 has a shape that further satisfies H₅₀/H₀≥0.80.

This makes it possible to further broaden the acceptable range of the inhibiting effect of color unevenness when there is a deviation in the positional. relationship between light-emitting element 20 and sealant 30.

Moreover, in light-emitting module 1 according to this embodiment, sealant 30 has a shape that further satisfies H₆₀/H₀≥0.70.

This makes it possible to further broaden the acceptable range of the inhibiting effect of color unevenness when there is a deviation in the positional relationship between light-emitting element 20 and sealant 30.

Moreover, in light-emitting module 1 according to this embodiment, sealant 30 has a shape that further satisfies H₇₀/H₀≥0.65.

This makes it possible to further broaden the acceptable range of the inhibiting effect of color unevenness when there is a deviation in the positional relationship between light-emitting element 20 and sealant 30.

Moreover, in light-emitting module 1 according to this embodiment, light-emitting elements 20 are mounted in a single line, and sealant 30 extends in a straight line and collectively seals light-emitting elements 20.

This makes it possible to achieve a light-emitting module that emits light in a continuous straight line.

Moreover, in light-emitting module 1 according to this embodiment, substrate 10 is oblong in shape, and light-emitting elements 20 are mounted along the lengthwise direction of substrate 10.

This makes it possible to achieve a long and thin linear light source that emits light in a line.

### Embodiment 2

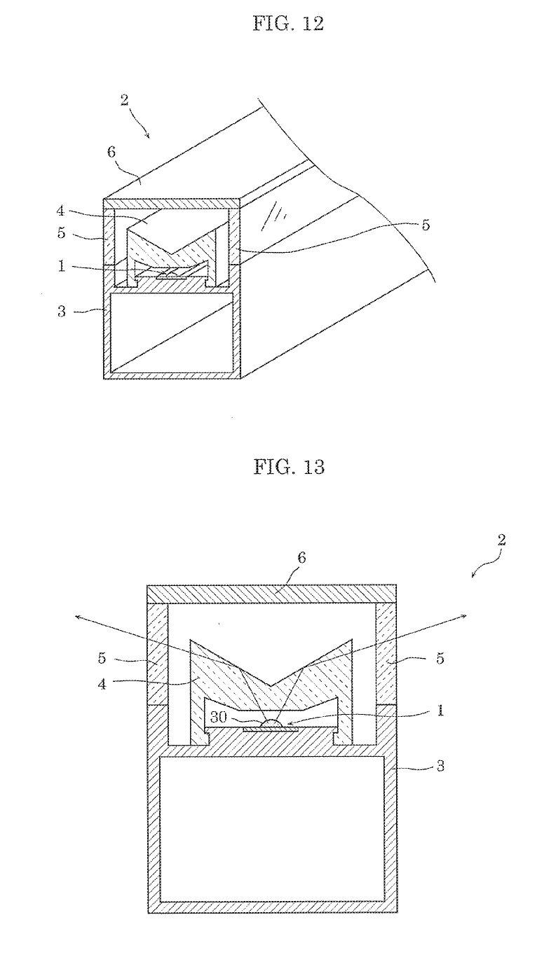

Next, lighting fixture 2 according to Embodiment 2 will be described with reference to FIG. 12 and FIG. 13. FIG. 12 is a perspective cross sectional view of lighting fixture 2 according to Embodiment 2. FIG. 13 is a cross sectional view of lighting fixture 2 according to Embodiment 2.

As illustrated in FIG. 12 and FIG. 13, lighting fixture 2 according to this embodiment is a wallwasher lighting apparatus, and is, for example, installed on or in the surface of a wall. In this case, lighting fixture 2 emits light in two directions, such as to the left and right or up and down, so as to illuminate the surface of the wall on either side of lighting fixture 2.

Lighting fixture 2 includes light-emitting module 1 according to Embodiment 1, pedestal 3, lens 4, pair of light-transmissive covers 5, and light blocking cover 6.

Pedestal 3 is a chassis that includes a supporting part that supports light-emitting module 1 and a housing part that houses a power supply unit (not illustrated in the drawings) for causing light-emitting module 1 to emit light. Pedestal 3 is oblong in shape so as to extend along the lengthwise direction of light-emitting module 1. For example, pedestal 3 is made of a metal or resin material.

Lens 4 is an optical component having a function of controlling the distribution of light emitted by light-emitting module 1. Lens 4 is disposed so as to cover light-emitting module 1. In this embodiment, lens 4 controls light distribution by refracting light emitted by light-emitting module 1 in two directions: left and right. More specifically, lens 4 controls the distribution of light so as to cause the light from light-emitting module 1 to be emitted toward pair of light-transmissive covers 5 disposed on the left and right of lens 4. In other words, the light emitted to the left and right from lens 4 is incident on pair of light-transmissive covers 5. Lens 4 is oblong in shape so as to extend along the lengthwise direction of light-emitting module 1. For example, lens 4 is made of a transparent resin or glass material.

Pair of light-transmissive covers 5 are disposed as side walls of pedestal 3. More specifically, one cover among pair of light-transmissive covers 5 is provided as the left wall of pedestal 3 and the other cover among pair of light-transmissive covers 5 is provide as the right wall of pedestal 3. Moreover, pair of light-transmissive covers 5 are disposed on the sides of lens 4. Each lens in the pair of light-transmissive covers 5 is oblong in shape so as to extend along the lengthwise direction of light-emitting module 1. For example, pair of light-transmissive covers 5 is made of a transparent resin or glass material. Note that in order to give pair of light-transmissive covers 5 light diffusion properties (light scattering properties), a milky white film may be formed on the surface of each light-transmissive cover 5, a light diffusing material may be dispersed in each light-transmissive cover 5, or minute protrusions and recesses may be formed on and in the surface of each light-transmissive cover 5.

Light blocking cover 6 opposes lens 4 so as to cover the opening of pedestal 3. With this, light from light-emitting module 1 that leaks upward above lens 4 can be blocked, making it possible to achieve a light distribution with a high degree of directionality in which light from light-emitting module 1 is emitted in two directions, left and right, from lens 4. Light blocking cover 6 is oblong in shape so as to extend along the lengthwise direction of light-emitting module 1. For example, light blocking cover 6 is made of a transparent resin or metal material.

In this way, light-emitting module 1 can be used as an oblong wallwasher lighting fixture 2.

### VARIATION

Hereinbefore, light-emitting module 1 and lighting fixture 2 according to the present disclosure has been described based on embodiments, but the present disclosure is not limited to the above embodiments.

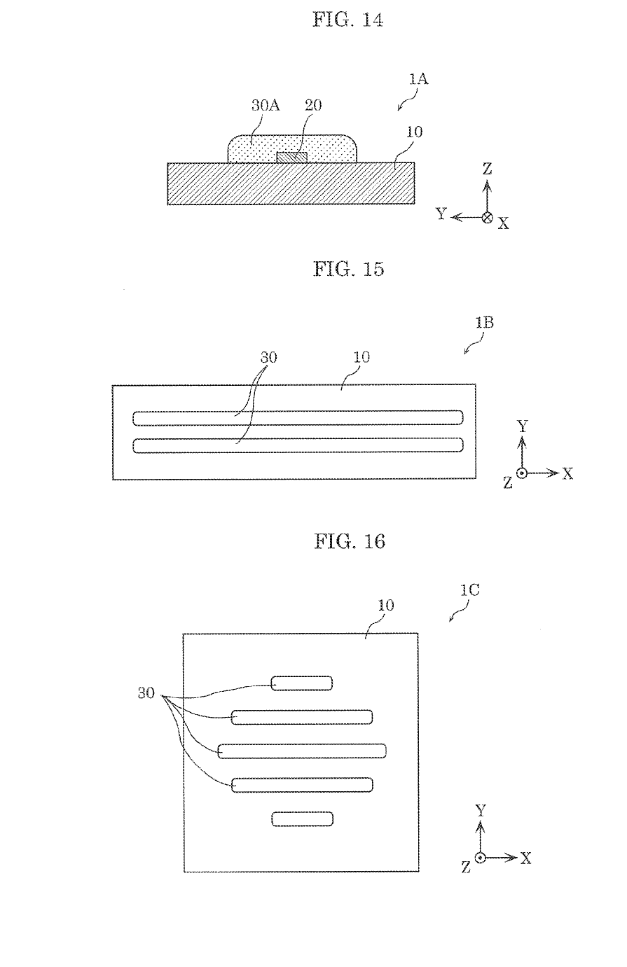

For example, in Embodiment 1 above, the contour of the surface of sealant 30 in a YZ cross section has an overall curved shape, but this example is not limiting. For example, as exemplified in light-emitting module 1A illustrated in FIG. 14, a portion of the contour of the surface of sealant 30A in a YZ cross section may include a straight line. This configuration makes it possible to further inhibit color unevenness when there is a deviation in the positional relationship between light-emitting element 20 and sealant 30.

Moreover, in Embodiment 1 above, light-emitting elements 20 are arranged in no more than one line, but light-emitting elements 20 may be arranged in a plurality of lines. In this case, sealant 30 may extend in a plurality of lines, each corresponding to one of the lines of light-emitting elements 20. For example, as exemplified in light-emitting module 2B illustrated in FIG. 15, when light-emitting elements 20 are arranged in two lines, sealant 30 may extend in two lines so as to correspond to the number of lines of light-emitting elements 20.

Moreover, in Embodiment 1 above, substrate 10 has an oblong shape, but the shape of substrate 10 is not limited to this example. For example, as exemplified in light-emitting module 1C illustrated in FIG. 16, a square substrate 10 may be used. Moreover, as illustrated in FIG. 16, when sealant 30 is formed in a plurality of lines, the lengths of the lines of sealant 30 may vary.

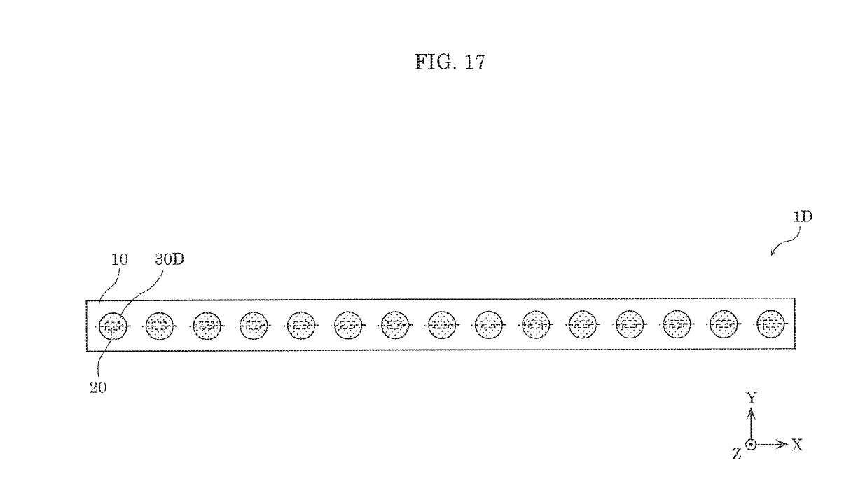

Moreover, in Embodiment 1 above, sealant 30 is formed so as to collectively seal all light-emitting elements 20, but sealant 30 is not limited to this example. For example, as exemplified in light-emitting module 1D illustrated in FIG. 17, sealant 30D may be formed in a plurality of discrete units that individually seal light-emitting elements 20.

Moreover, in Embodiment 1 above, light-emitting module 1 is configured to emit white light using blue LED chips and yellow phosphor, but light-emitting module 1 is not limited to this example. For example, a configuration in which blue LED chips are paired with a phosphor-containing resin containing red and green phosphor may be used to produce white light.

Moreover, in Embodiment 1 above, LED chips that emit light of a color other than blue may be used. For example, when ultraviolet LED chips that emit ultraviolet light shorter in wavelength than the blue light emitted by the blue LED chips, a configuration in which the ultraviolet LED chips are paired with phosphors that emit the three primary colors (red, green, and blue) when excited mainly by ultraviolet light may be used.

Moreover, in Embodiment 1 above, phosphor is used as the wavelength converter, but the wavelength converter is not limited to this example. For example, any material that includes a substance that absorbs light of a given wavelength and emits light of a different wavelength, such as a semiconductor, metal complex, organic dye, or pigment, may be used as the wavelength converter.

Moreover, in Embodiments 1 and 2 above, light-emitting module 1 may be configured such that the light it emits is capable of being dimmed or changed in color.

Moreover, in Embodiment 2 above, an example is given in which light-emitting module 1 is used in a wallwasher lighting fixture, but this example is not limiting. For example, light-emitting module 1 may be used in an oblong light apparatus such as a tube lamp or base light, or in a different lighting apparatus, such as a down light, spot light, ceiling light, or bulb-shaped lamp. Moreover, light-emitting module 1 can also be used in a device used for purposes other than lighting purposes.

While the foregoing has described one or more embodiments and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present teachings.

What is claimed is:

1. A light-emitting module, comprising:
a substrate;
a light-emitting element mounted on the substrate; and
a sealant that seals the light-emitting element,
wherein the sealant includes a resin material containing a wavelength converter, and
a cross section of the sealant taken through the light-emitting element satisfies H_{MAX}/W≤0.3, where W is a width of a base of the sealant and H_{MAX} is a maximum height of the sealant.

2. The light-emitting module according to claim 1, wherein
0.1≤H_{MAX}/W.

3. The light-emitting module according to claim 1, wherein
H₀=H_{MAX},
where, in the cross section, a direction pointing straight upward from a center of the base of the sealant is 0 degrees, and H₀ is a height of the sealant at the center of the base of the sealant.

4. The light-emitting module according to claim 3, wherein
H₃₀/H₀≥0.95,
where, in the cross section, H₃₀ is a height of the sealant in a direction 30 degrees from the center of the base of the sealant.

5. The light-emitting module according to claim 3, wherein
H₄₀/H₀≥0.90,
where, in the cross section, H₄₀ is a height of the sealant in a direction 40 degrees from the center of the base of the sealant.

6. The light-emitting module according to claim 3, wherein
H₅₀/H₀≥0.80,
where, in the cross section, H₅₀ is a height of the sealant in a direction 50 degrees from the center of the base of the sealant.

7. The light-emitting module according to claim 3, wherein
H₆₀/H₀≥0.70,
where, in the cross section, H₆₀ is a height of the sealant in a direction 60 degrees from the center of the base of the sealant.

8. The light-emitting module according to claim 3, wherein
H₇₀/H₀≥0.65,
where, in the cross section, H₇₀ is a height of the sealant in a direction 70 degrees from the center of the base of the sealant.

9. The light-emitting module according to claim 1, wherein
the light-emitting element comprises a plurality of light-emitting elements mounted in a single line, and
the sealant extends in a straight line and collectively seals the plurality of light-emitting elements.

10. The light-emitting module according to claim 9, wherein
the substrate is oblong in shape, and
the plurality of light-emitting elements are mounted along a direction of the substrate.

11. A lighting fixture, comprising:
the light-emitting module according to claim 1.
